(19) United States
(12) Patent Application Publication
(10) Pub. No.: US 2007/0111480 A1
(43) Pub. Date: May 17, 2007

(54) Wafer product and processing method therefor

(75) Inventors: Yumi Maruyama, Kariya-city (JP); Muneo Tamura, Nagoya-city (JP); Tetsuo Fujii, Toyohashi-city (JP); Hirotsugu Funato, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/586,558

(22) Filed: Oct. 26, 2006

(30) Foreign Application Priority Data
Nov. 16, 2005 (JP) 2005-331209
Nov. 16, 2005 (JP) 2005-331218
Jul. 19, 2006 (JP) 2006-196890

(51) Int. Cl. H01L 21/00

(52) U.S. Cl. 438/463

(57) ABSTRACT

A semiconductor wafer has two faces, one of which is a laser light incident face. A dicing sheet is attached to the other face of the wafer, so that it is stretched to thereby apply tensile stress to a laser-reformed region and cause cutting with the reformed region taken as a starting point for cutting. A protection layer, such as light scattering projections and depressions, a light scattering member or a light reflecting member, is provided between the wafer and the dicing sheet to scatter or reflect the laser light passing through the wafer. Thus, the dicing sheet can be protected from being damaged because the laser light converging point is not formed in the dicing sheet.

### CROSS REFERENCE TO RELATED APPLICATION

This application is based on and incorporates herein by reference Japanese Patent Applications No. 2005-331209 filed on Nov. 16, 2005, No. 2005-331218 filed on Nov. 16, 2005 and No. 2006-196890 filed on Jul. 19, 2006.

### FIELD OF THE INVENTION

The present invention relates to a wafer product and a processing method for the wafer product. In particular, the present invention relates to a wafer product that is cut and separated by cutting with a reformed region due to multiphoton absorption, formed by irradiation with laser light, taken as a starting point for cutting and a processing method for the wafer product.

### BACKGROUND OF THE INVENTION

Laser dicing technologies have been developed for cutting and separating (dividing) a wafer-like object to be processed into a plurality of chips using laser light.

For example, a wafer-like object such as a semiconductor substrate to be processed is irradiated with laser light with a light-converging point positioned inside the object. Thus, a reformed (modified) region due to multiphoton absorption is formed inside the object. The reformed region may be a reformed region including crack region, a reformed region including molten processed region, and a reformed region including region with changed refractive index. A region to be a starting point for cutting is formed inside the object by this reformed region. This region is formed within the object inside by a predetermined distance from the laser light incident face of the object along a line along which the object to be processed should be cut. The object to be processed is cut by cutting with this region taken as the starting point. This is disclosed in U.S. Pat. No. 6,992,026 (JP 3408805) for instance.

As described above, an object to be processed is irradiated with laser light with the light-converging point of the laser light positioned inside the object. A reformed region is thereby formed within the object along a line along which the object should be cut. At the same time, the position of the light-converging point of laser light in the direction of incidence of the laser light, applied to the object, on the object is changed. The reformed region is thereby plurally formed so that they are lined in the direction of incidence. This is disclosed in U.S. Pat. No. 6,992,026.

According to this technology, multiple reformed regions are formed so that they are lined in the direction of incidence. This increases a number of points that make a starting point when an object to be processed is cut. As a result, even a thick object can be cut.

An expansible sheet is attached to either face of a flat object to be processed including a substrate, and the other face of the object to be processed is taken as laser light incident face. Then, the object is irradiated with laser light with the light-converging point positioned inside the substrate, and a reformed region (molten processed region) due to multiphoton absorption is thereby formed. A starting point region for cutting is formed by this reformed region inside by a predetermined distance from the laser light incident face along a line along which the object should be cut. Then, the sheet is stretched to cut the object into multiple portions, starting with the starting point region for cutting, so that spacing is provided between the individual portions. This is disclosed in US 2005/0202596 (JP 2005-1001A).

According to this technology, the starting point region for cutting is formed inside the substrate, and then the sheet is stretched. Therefore, tensile stress can be favorably applied to the starting point region for cutting, and the substrate can be accurately split and cut by relatively small force, starting with the starting point region for cutting.

An attempt has been recently made to implement the following using the above laser dicing technology: a reformed region (reformed layer) is formed inside a wafer; and the wafer is cut and separated into individual chips (semiconductor chips) by cutting using the reformed region as starting point for cutting.

However, in this technology, the light-converging point cannot be positioned inside the wafer in the cases, where there is variation from wafer to wafer and the wafer to be processed is too thin, or where the setting of the light-converging point of laser light is inappropriate. In these cases, the light-converging point can be positioned beyond the face (rear face) of the wafer opposite its laser light incident face (front face).

That is, the focal point of laser light cannot be positioned inside the wafer when the wafer is too thin or when the setting of the focal point is inappropriate. As a result, the focal point can be positioned beyond the face of the wafer opposite its laser light incident face.

According to US 2005/0202596, for example, an expansible sheet attached to the rear face of a wafer can be melted and damaged due to laser light when the light-converging point of the laser light is positioned inside the sheet. Thus, when the sheet is stretched to cut and separate the wafer, the tensile stress from the sheet cannot be evenly applied to the wafer. Therefore, it becomes difficult to appropriately cut and separate the wafer.

In cases where the light-converging point of laser light is positioned within the stage (specimen support) of a laser machine with a wafer placed on it, the stage can be melted and damaged by the laser light and lose planarity. Thus, when the next wafer is placed on the stage and irradiated with laser light, the light-converging point cannot be positioned in a desired position inside the wafer, and a reformed region cannot be formed in a due position. As a result, it becomes difficult to accurately cut and separate the wafer with the reformed region taken as the starting point.

Further, according to US 2005/0202596, as illustrated in FIG. 16A, a wafer W that is formed of semiconductor, such as silicon, and has semiconductor devices D formed over its light incident face is prepared. Its rear face opposite the light incident face is bonded to an extensible resin sheet S. A bonding layer B to which ultraviolet curing adhesive or the like is applied is formed over the entire face of the sheet S to which the wafer W is to be bonded. The entire rear face of the wafer W is bonded to the bonding layer B.

A laser head H that projects laser light L is provided with a condenser lens CV that condenses the laser light L, and converges the laser light L at a predetermined focal position. In a reformed region formation process, the laser head H is moved along a planned dividing line DL along which the wafer W is to be divided (to the near side in the figure). At this time, the laser head is moved under laser light irradiation conditions so set that the light-converging point P of the laser light L is positioned in a place at a depth of Dp from the front face of the wafer W. Then, the wafer W is irradiated with the laser light L from its front face side. Thus, a reformed region R due to multiphoton absorption is formed in the pass at a depth of Dp through which the light-converging point P of the laser light L is caused to make scanning movement.

The reformed region R can be plurally formed in multiple places at arbitrary depths within the range of the thickness of the wafer W by taking the following procedure: the depth Dp of the light-converging point P is adjusted along a planned dividing line DL, and the light-converging point P is moved in the direction of the thickness of the wafer W.

Multiphoton absorption is defined as a substance absorbing multiple homogeneous or heterogeneous photons. Because of this multiphoton absorption, a phenomenon designated as optical damage occurs at the light-converging point P and in the vicinity of the point within the wafer W. This induces thermal distortion and cracks to occur in that area. As a result, a layer in which cracks aggregate, that is, a reformed region R is formed.

Subsequently, stress is applied to the wafer W in the in-plane direction indicated by arrows F1 and F2 in FIG. 16B. The cracks are thereby developed in the direction of the substrate thickness with the reformed regions R taken as starting point, and the wafer W is thereby divided along the planned dividing lines DL to obtain semiconductor chips C.

However, the reformed region R is introduced in an area in the vicinity of the rear face, a face to be joined with the sheet S. In cases where, at this time, the laser light L passes through the wafer W and its light-converging point P is positioned inside the bonding layer B or the sheet S, their quality can be changed by heat affection. Portions whose quality has been changed in the bonding layer B and the sheet S lose extensibility and become frangible. For this reason, when the wafer W is divided, they can fly as powder in all directions and stick to semiconductor devices D.

To avoid this phenomenon, the area in the vicinity of the rear face of the wafer W can be protected from being irradiated with laser light L. In cases where this is done, a sufficient amount of reformed regions R cannot be formed aiming at the area in the vicinity of the rear face that becomes a starting point for division. As a result, great force is required to divide the substrate. This will become a cause of a portion left undivided in the wafer W.

### SUMMARY OF THE INVENTION

The present invention has an object to provide a wafer product and a processing method for the wafer product, wherein a light-converging point of laser light can be positioned without being positioned beyond the face opposite a laser light incident face.

According to the present invention, a wafer product separable by cutting at a reformed region formed by laser light comprises a wafer, a dicing sheet and a protection layer. The wafer has two faces, one of which is a laser light incident face and the other of which is opposite the light incident face in a direction of wafer thickness. The dicing sheet is attached to the other face of the wafer for cutting the wafer into a plurality of chips. The protection layer is provided between the wafer and the dicing sheet for scattering or reflecting the laser light passing though the wafer thereat to protect the dicing sheet from the laser light.

The protection layer may be projections and depressions uniformly formed on the other face of the wafer, or a large number of particles provided on the other face, so that the laser light may be scattered not to enter the dicing sheet. Alternatively, the protection layer may be a reflector that reflects the laser light not to enter the dicing sheet.

### BRIEF DESCRIPTION OF THE DRAWINGS

The above and other objects, features and advantages of the present invention will become more apparent from the following detailed description made with reference to the accompanying drawings. In the drawings:

FIG. 1 is an enlarged sectional view illustrating how the wafer is irradiated with laser light to form a reformed region in a first embodiment of the invention;

FIG. 2 is an enlarged sectional view illustrating how the wafer is irradiated with laser light to form a reformed region in the first embodiment of the invention;

FIG. 3 is an enlarged sectional view illustrating how the wafer whose rear face is a smooth surface is irradiated with laser light from the front face side to form a reformed region;

FIG. 4 is an enlarged sectional view illustrating how the wafer whose rear face is a smooth surface is irradiated with laser light from the front face side to form a reformed region;

FIG. 5 is an enlarged sectional view illustrating how the wafer whose rear face is a roughened surface is irradiated with laser light from the rear face side with the rear face taken as incident face to form a reformed region;

FIG. 6 is an enlarged sectional view illustrating how the wafer whose rear face is a roughened surface is irradiated with laser light from the rear face side with the rear face taken as incident face to form a reformed region;

FIG. 7 is a graph showing the result of experiments conducted to examine whether or not a reformed region is formed, taking the following procedure: YAG laser with a wavelength of 1.064 μm is used as the laser light, and the maximum height in surface roughness of the rear faces of wafers is varied;

FIG. 8 is an enlarged sectional view illustrating how the wafer is irradiated with laser light to form a reformed region in a second embodiment of the invention;

FIG. 9 is an enlarged sectional view illustrating how the wafer is irradiated with laser light to form a reformed region in a third embodiment of the invention;

FIG. 10A is an enlarged sectional view illustrating how the wafer is irradiated with laser light to form a reformed region in a fourth embodiment of the invention;

FIG. 10B is an enlarged sectional view illustrating how the wafer is irradiated with laser light to form a reformed region in a fifth embodiment of the invention;

FIG. 11A is a plan view of a wafer in a sixth embodiment of the present invention;

FIG. 11B is a sectional view taken along line 11B-11B in FIG. 11A.

FIG. 12 is a schematic sectional view illustrating a method for irradiating a wafer with laser light;

FIG. 13 is an enlarged sectional view illustrating how laser light is reflected by an aluminum sheet formed over a wafer;

FIG. 14 is an enlarged sectional view illustrating a method for converging laser light, reflected by an aluminum sheet, to form a reformed region in a seventh embodiment;

FIG. 15 is an enlarged sectional view of a construction with which an aluminum sheet is formed on a rear face at least on planned dividing lines;

FIG. 16A is an enlarged sectional view illustrating a process in which a reformed region is formed by laser light irradiation; and

FIG. 16B is an enlarged sectional view illustrating a process in which a wafer is divided.

### DETAILED DESCRIPTION OF THE PREFERRED EMBODIMENTS

### First Embodiment

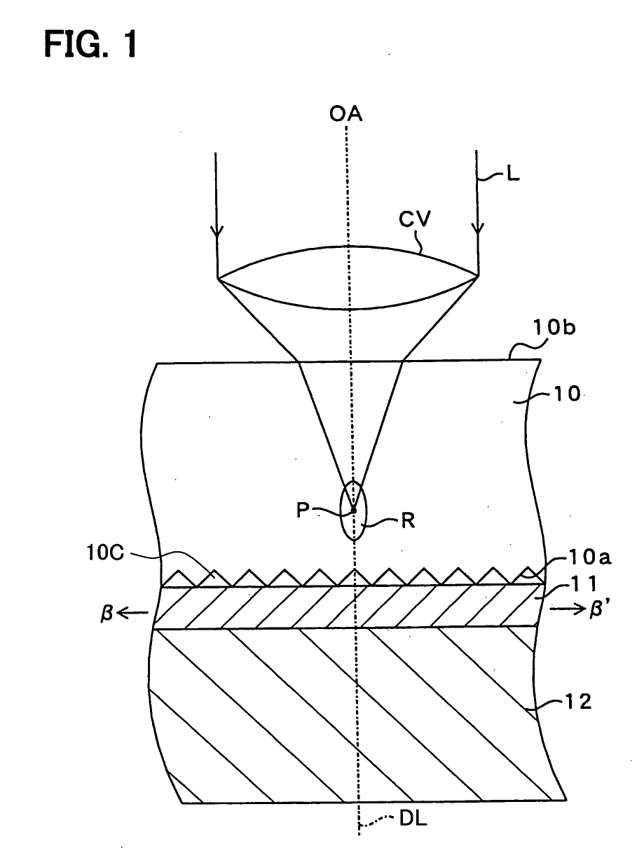

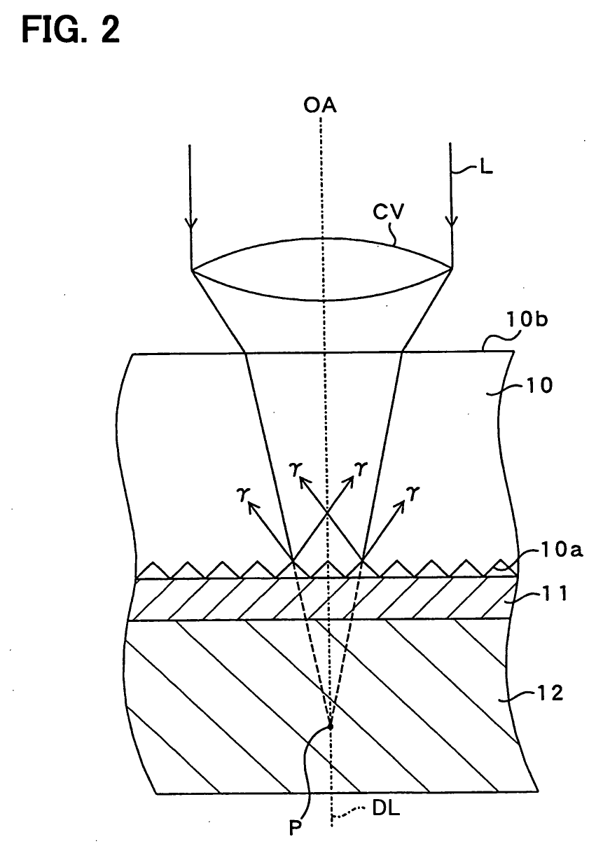

Referring first to FIGS. 1 and 2, a bulk silicon wafer 10 is formed of a bulk material of single crystal silicon, and its rear face 10a is a roughened surface in which substantially uniform projections and depressions 10c are formed as a protection layer. To make the rear face 10a of the wafer 10 a roughened surface, that is, protection layer, any processing method may be used. Examples of the processing method include: a method in which the rear face 10a is immersed in acid solution or alkaline solution that affects the material for forming the wafer 10 and chemically treated; and a method in which the rear face is processed by mechanical polishing, such as sandblast.

To cut and separate the wafer 10 using a laser dicing technology, the following procedure is taken: a dicing sheet (dicing film, dicing tape, expand tape) 11 is stuck to the rear face 10a of the wafer 10. The dicing sheet 11 is composed of expansible plastic sheet material that is stretched by applying heat or force in the direction of expansion. It is bonded to the entire rear face 10a of the wafer 10 by a binding material (not shown). Thus, the wafer 10 and the dicing sheet 11 form a wafer product. The wafer product is placed on a stage (specimen support) 12 of a laser machine (not shown) with the rear face 10a of the wafer 10 facing downward. This brings the dicing sheet 11 into contact with the upper face of the stage 12.

The laser machine includes a laser light source (not shown) that projects laser light L and a condenser lens CV. The laser light L is applied to the front face (laser light incident face) 10b of the wafer 10 through the condenser lens CV with the optical axis OA of the laser light L perpendicular to the front face 10b of the wafer 10. Thus, the light-converging point (focal point) P where the laser light L is converged is positioned in a predetermined position inside the wafer 10. As a result, a reformed region (reformed layer) R is formed at the location. of the light-converging point P inside the wafer 10.

For example, laser light of YAG (Yttrium Aluminum Garnet) laser with a wavelength of 1.064 μm in the infrared light region can be used as the laser light L. The reformed region R includes a molten processed region mainly due to multiphoton absorption, formed by irradiation with the laser light L.

The location of the light-converging point P within the wafer 10 is locally heated by the multiphoton absorption of the laser light L. It is melted by this heat, and then set again. Thus, a region melted and then set again within the wafer 10 becomes the reformed region R.

That is, the molten processed region is a region whose phase or crystal structure has been changed. In other words, the molten processed region is any of a region where the single crystal silicon has been transformed into amorphous silicon inside the wafer 10, a region where single crystal silicon has been transformed into polycrystalline silicon, and a region where single crystal silicon has been transformed into a structure containing amorphous silicon and polycrystalline silicon. Since the wafer 10 is a bulk silicon wafer, the molten processed region is mainly composed of polycrystalline silicon.

The molten processed region is not formed by the laser light L being absorbed within the wafer 10. That is, it is not formed by ordinary heating by laser light. The molten processed region is formed mainly by multiphoton absorption. For this reason, the laser light L is hardly absorbed in the locations inside the wafer 10 other than that of the light-converging point P, and the front face 10b of the wafer 10 is not melted.

With the depth position of the light-converging point P inside the wafer 10 kept constant, the laser machine applies the laser light L in a pulse pattern and further causes it to make scanning movement. The laser machine thereby moves the light-converging point P along a straight line DL along which the wafer 10 should be cut. Instead, with the position of laser light L application fixed, the stage 12 may be moved in the direction orthogonal to the direction of laser light L application. The direction of laser light L application is the direction of incidence of the laser light L on the front face 10b of the wafer 10.

That is, the light-converging point P is moved relative to the wafer 10 along the line DL along which the wafer 10 should be cut by causing the laser light L to make scanning movement or moving the wafer 10.

As stated above, with the depth position of the light-converging point P within the wafer 10 kept constant, the wafer 10 is irradiated with the laser light L in a pulse pattern and further the light-converging point P is moved relative to the wafer. Thus, a reformed region group composed of multiple reformed regions R at certain intervals in the direction parallel to the front and rear faces 10b and 10a of the wafer 10 is formed in a certain depth position from the front face 10b of the wafer 10. That is, the reformed region group is formed in a position inside an area at a certain distance from the laser light L incident face.

The depth of the light-converging point P within the wafer 10 is equivalent to the distance from the front face (laser light L incident face) 10b of the wafer 10 to the light-converging point P.

Thus, the reformed region group composed of the multiple reformed regions R is formed inside the wafer 10. Thereafter, the dicing sheet 11 is stretched in the horizontal direction (the directions indicated by arrows β and β′ in FIG. 1) with respect to the line DL along which the wafer should be cut, and tensile stress is thereby applied to each reformed region R.

Thus, shearing stress is produced within the wafer 10, and a crack is made in the direction of the depth of the wafer 10 with each reformed region R taken as starting point. When the grown cracks reach the front and rear faces 10b and 10a of the wafer 10, the wafer 10 is thereby cut and separated.

As mentioned above, each reformed region R is formed along the line DL along which the wafer should be cut. Therefore, the following can be implemented by stretching the dicing sheet 11 to favorably apply tensile stress to each reformed region R, and thereby cutting the wafer with each reformed region R taken as starting point for cutting: the wafer 10 can be accurately cut and separated by relatively small force without causing an undesired crack in the wafer 10.

Over the front face 10b of the substantially disk-shaped wafer 10 of thin plate, there are aligned and arranged a large number of chips (not shown) in a grid pattern. The lines DL along which the wafer should be cut are disposed between the chips. That is, the multiple lines DL along which the wafer 10 should be cut are disposed in a lattice pattern in the front face 10b of the wafer 10.

For this reason, the wafer 10 can be cut and separated into individual chips by forming each reformed regions R with respect to each of the lines DL along which the wafer should be cut, and then stretching the dicing sheet 11.

The light-converging point P cannot be positioned inside the wafer 10 in the following cases: cases where there is variation from wafer 10 to wafer 10 and the wafer 10 to be processed is too thin; and cases where the setting of the light-converging point P of laser light L is inappropriate. In these cases, the light-converging point P can be positioned beyond the rear face 10a of the wafer 10 opposite its front face (laser light L incident face) 10b.

The focal point P of laser light L cannot be positioned inside the wafer 10 when the wafer 10 is too thin or when the setting of the focal point P is inappropriate. As a result, the focal point P can be positioned beyond the face (rear face) 10a of the wafer 10 opposite its laser light L incident face (front face) 10b.

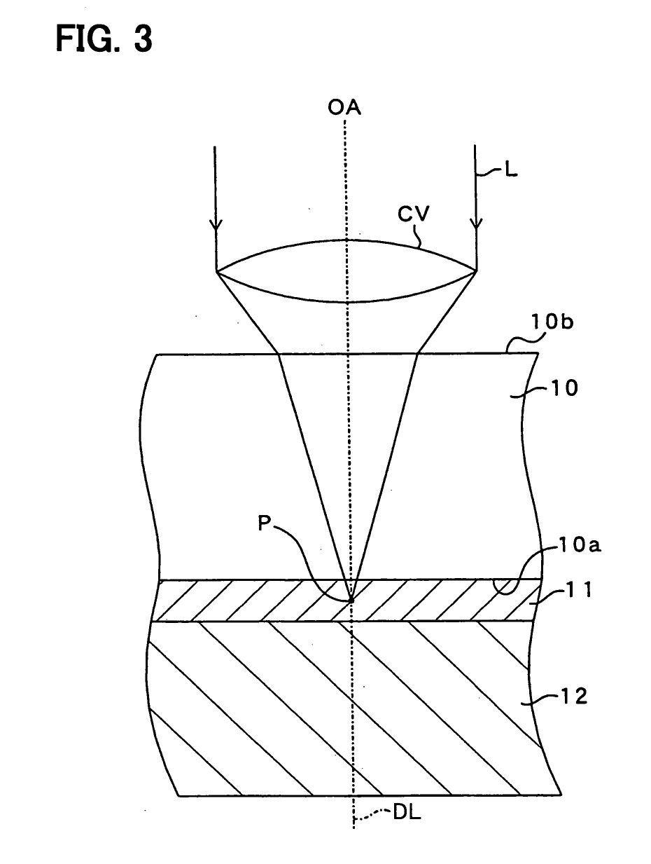

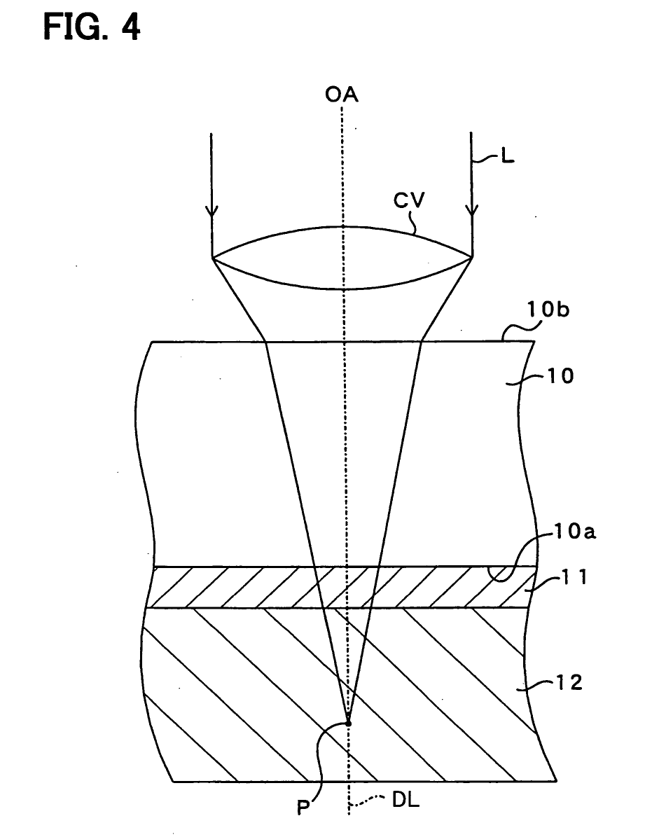

Referring to FIG. 3 and FIG. 4 explaining how the wafer 10 is irradiated with the laser light L from its front face 10b side to form a reformed region when the rear face 10a of the wafer is a smooth surface. They schematically illustrate a longitudinal section of a wafer 10.

When the light-converging point P of laser light L is positioned inside the dicing sheet 11 as illustrated in FIG. 3 as an example, the dicing sheet 11 can be melted and damaged by the laser light L. Consequently, when the dicing sheet 11 is stretched to cut and separate the wafer 10, tensile stress from the dicing sheet 11 cannot be evenly applied to the wafer 10. This makes it difficult to normally cut and separate the wafer 10.

When the light-converging point P of laser light L is positioned inside the stage 12, as illustrated in FIG. 4, the stage 12 can be melted and damaged by the laser light L and can lose planarity. Consequently, when the next wafer 10 is placed on the stage 12 and irradiated with laser light L, the light-converging point P cannot be positioned in a desired position inside the wafer 10 and the reformed region R cannot be formed in a due position. This makes it difficult to accurately cut and separate the wafer 10 with the reformed region R taken as starting point.

In the first embodiment, meanwhile, the rear face 10a of the wafer 10 is roughened as illustrated in FIG. 2. Therefore, even when the light-converging point P is erroneously set to a point beyond the rear face 10a, the above problem does not arise. Since the laser light L is scattered by the rear face 10a, as indicated by arrows γ, the light-converging point P is not formed. As a result, the energy of laser light L at the erroneously set light-converging point P is significantly attenuated.

According to the first embodiment, therefore, the light-converging point P of laser light L is not positioned inside the dicing sheet 11, and the dicing sheet 11 can be prevented from being melted and damaged. Further, the light-converging point P of laser light L is not positioned within the stage 12, as illustrated in FIG. 2, and the stage 12 can be protected from being over-heating and damaged.

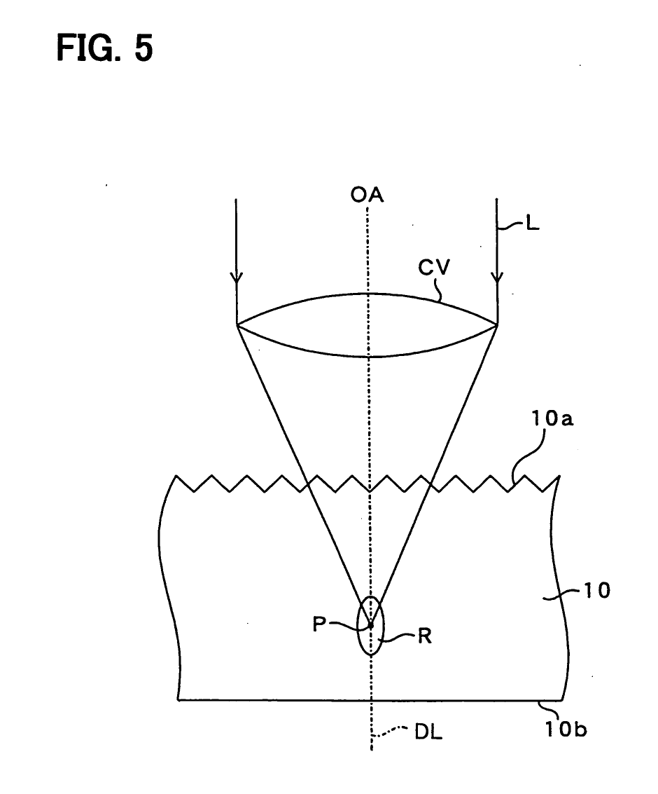

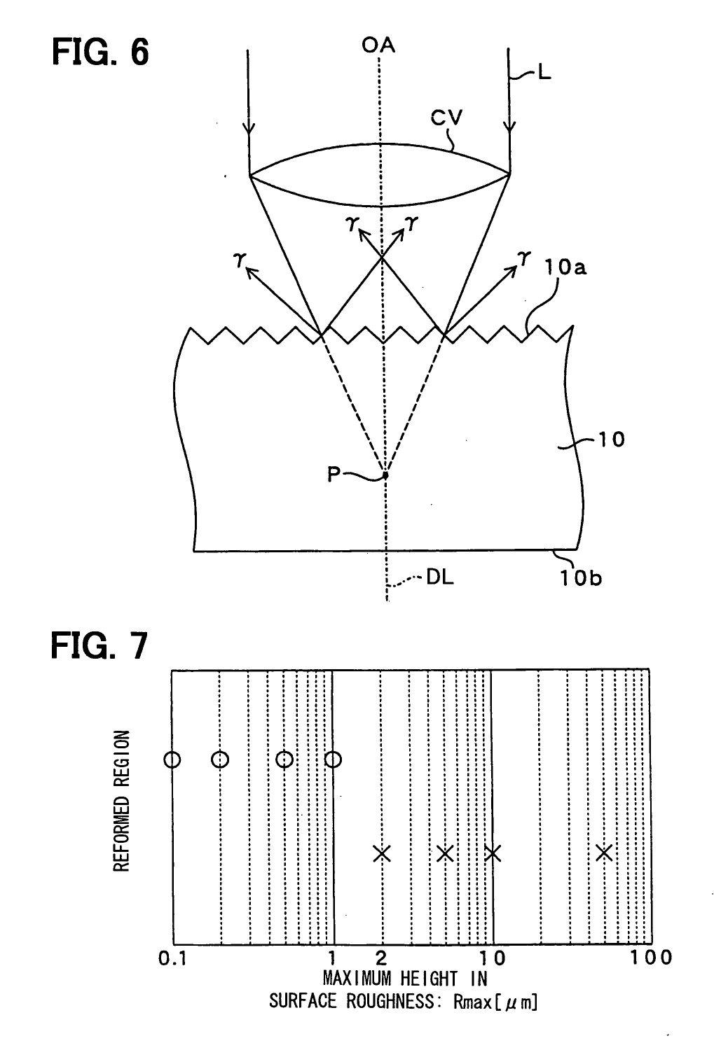

FIG. 5 and FIG. 6 show how the reformed region R is formed by irradiating the wafer 10 with the laser light L from its rear face 10a side with the rear face 10a taken as incident face when the rear face 10a is roughened. It schematically illustrates a longitudinal section of the wafer 10.

When the laser light L passes through the rear face 10a of the wafer 10, as illustrated in FIG. 5, the energy of the laser light L at the light-converging point P is considerable. As a result, the reformed region R is formed inside the wafer 10.

When the laser light L is scattered by the rear face 10a of the wafer 10, as illustrated in FIG. 6, the energy of the laser light L at the light-converging point P is attenuated. For this reason, the reformed region R is not formed inside the wafer 10.

FIG. 7 shows the result of experiments conducted to examine whether the reformed region R is formed inside the wafer 10, taking the following procedure: YAG laser with a wavelength of 1.064 μm is used as the laser light L, and the maximum height Rmax in the surface roughness of the laser light incident face (the rear face 10a of the wafer 10) is varied.

The maximum height Rmax (Ry) in surface roughness is a value according to a measuring method laid down in the JIS Standard “JIS B0601-1982.” It expresses the maximum height value, obtained by taking the following procedure, in micrometers (μm): the maximum height of a portion extracted from a profile curve by a reference length is measured in the direction of the axial magnification of the profile curve. This is equivalent to the distance between two straight lines parallel to an average line when the extracted portion is sandwiched between the two straight lines.

The following is understood from FIG. 7: when the maximum height Rmax in the surface roughness of the rear face 10a of the wafer 10 is equal to or larger than the wavelength λ (=1.064 μm) of laser light L, the reformed region R is not formed. This is indicated with the mark X in FIG. 7, while the mark 0 indicates occurrence of the reformed region.

There is no difference in the state of scattering of laser light L between the following cases: cases where the wafer 10 is irradiated with laser light L from its front face 10b side with the front face 10b taken as the light incident face (cases in FIG. 1 and FIG. 2); and cases where the wafer 10 is irradiated with the laser light L from its rear face 10a side with the rear face 10a taken as the incident face (cases illustrated in FIG. 5 and FIG. 6).

It is noted that even in the following cases, the reformed region R is not formed as long as the maximum height Rmax in the surface roughness of the rear face 10a of the wafer 10 is equal to or larger than the wavelength λ of the laser light L: cases where laser light with any other wavelength than 1.064 μm is used; and cases where any other kind of laser than YAG laser is used.

Examples of other kinds of laser than YAG laser include solid state laser, such as ruby laser and glass laser, semiconductor laser, such as gallium arsenide laser and indium gallium arsenide laser, and gas laser, such as excimer laser and carbon dioxide laser.

Therefore, a light-converging point P can be positioned without fail not to be positioned beyond the rear face 10a of the wafer 10 opposite its front face (laser light L incident face) 10b by taking the following measure: the maximum height Rmax in the surface roughness of the rear face 10a of the wafer 10 is so set that it is equal to or larger than the wavelength λ of laser light L used (Rmax≧λ). This can be implemented even when the wafer 10 is irradiated with laser light L from its front face 10b side with the front face 10b taken as the incident face, as in the first embodiment (FIG. 1 and FIG. 2). This protects the dicing sheet 11 or the stage 12 from being melted and damaged by the laser light L.

Thus, the laser light L can be restricted without fail from forming the focal point P beyond the face (rear face) 10a of the wafer 10 opposite its laser light L incident face (front face) 10b by taking the following measure: the maximum height Rmax in the surface roughness of the rear face 10a of the wafer 10 is so set that it is equal to or larger than the wavelength λ of laser light L used.

### Second Embodiment

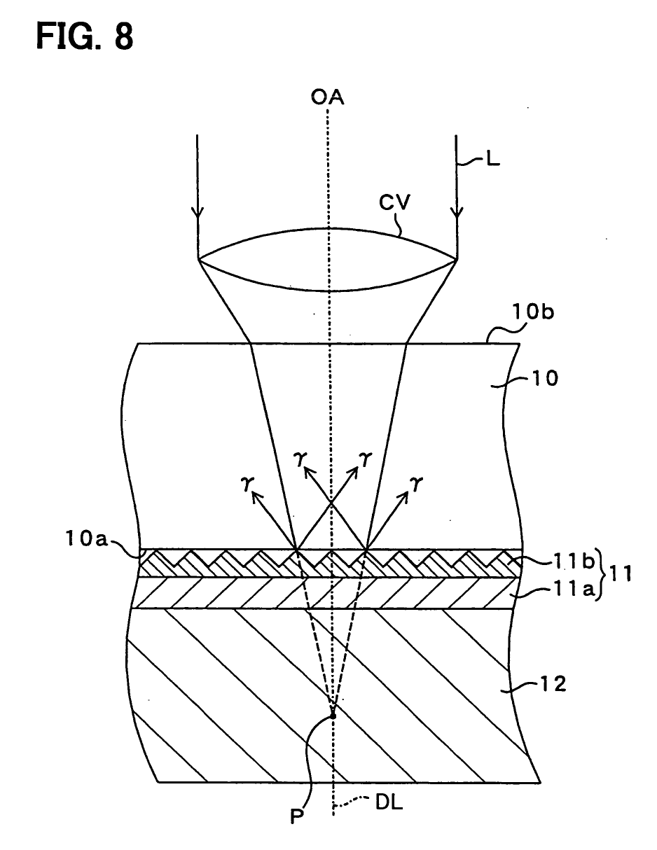

The second embodiment shown in FIG. 8 is different from the first embodiment in the following points.

(2.1) The rear face 10a of the wafer 10 is a smooth surface.

(2.2) The dicing sheet 11 is composed of a sheet base material 11a and a binding material 11b, and the binding material 11b is applied to the entire front face of the sheet base material 11a.

(2.3) The sheet base material 11a is formed of an expansible plastic sheet material, and its front face is a smooth surface. The binding material 11b is formed of a thin sheet of adhesive having the property of bonding together the wafer 10 and the sheet base material 11a. An example of this adhesive is acrylic adhesive. The front face of the binding material 11b is a roughened surface in which substantially uniform projections and depressions are formed, so that the binding material functions as a protection layer for protecting the base material 11a from the laser light L.

(2.4) The rear face 10a of the wafer 10 is in contact only with the projections of the projections and depressions formed in the front face of the binding material 11b. That is, an air gap is formed between the rear face 10a of the wafer 10 and the depressions of the projections and depressions formed in the front face of the binding material 11b.

Thus, the front face of the binding material 11b (the face joined with the rear face 10a of the wafer 10) is a roughened surface. Therefore, even when the light-converging point P is erroneously set to a point beyond the rear face 10a of the wafer 10, the above problem does not arise. Since the laser light L is scattered by the front face of the binding material 11b, as indicated by arrows γ, the light-converging point P is not formed. As a result, the energy of laser light L at the erroneously set light-converging point P is significantly attenuated.

Therefore, the same effect as in the first embodiment is provided in the second embodiment. That is, the light-converging point P of laser light L is not formed in the dicing sheet 11 or the stage 12, and the dicing sheet 11 and the stage 12 can be protected from being melted and damaged.

Also, in the second embodiment, laser light L can be restricted without fail from forming a focal point P beyond the face (rear face) 10a of the wafer 10 opposite its laser light L incident face (front face) 10b due to the same operation as in the first embodiment by taking the following measure: the maximum height Rmax in the surface roughness of the front face of the binding material 11b is so set that it is equal to or larger than the wavelength λ of laser light L used (Rmax≧λ).

To make the front face of the binding material 11b a roughened surface, any processing method may be used. Examples of the processing method include: a method in which the dicing sheet 11 is immersed in acid solution or alkaline solution that affects the adhesive that is a material for forming the binding material 11b and chemically treated; a method in which the binding material is processed by mechanical polishing, such as sandblast; and a method in which the binding material is processed by pressing, that is, a jig with projections and depressions formed in its front face is pressed against the partially set binding material 11b.

### Third Embodiment

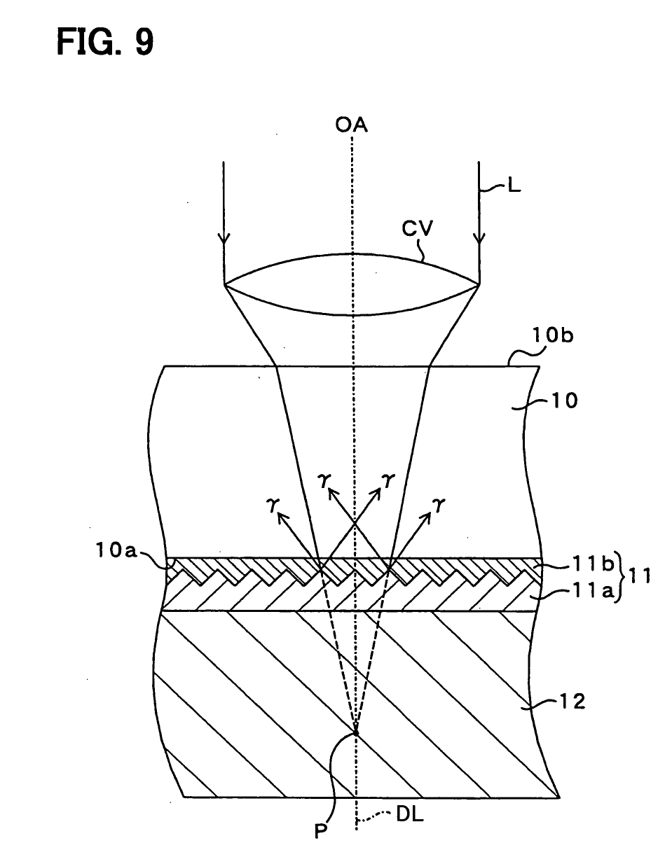

In the third embodiment shown in FIG. 9, the rear face 10a of the wafer 10 is a smooth surface and the dicing sheet 11 is formed of the sheet base material 11a and the binding material 11b as described in Sections 2.1 and 2.2 with regard to the second embodiment.

The third embodiment is different from the second embodiment only in the following:

(3.1) The front face of the sheet base material 11a is a roughened surface in which substantially uniform projections and depressions are formed. The front face of the binding material 11b is a smooth surface.

(3.2) The entire rear face 10a of the wafer 10 is stuck to the front face of the binding material 11b. The front face (in contact with the binding material 11b) of the sheet base material 11a is a roughened surface.

Therefore, even when a light-converging point P is erroneously set to a point beyond the rear face 10a of the wafer 10, the above problem does not arise. Since the laser light L is scattered by the front face of the sheet base material 11a, as indicated by arrows γ, the light-converging point P is not formed. As a result, the energy of laser light L at the erroneously set light-converging point P is significantly attenuated. Therefore, the same effect as in the first embodiment is provided in the third embodiment.

Also, in the third embodiment, the above effect can be provided without fail due to the same operation as in the first embodiment by taking the following measure: the maximum height Rmax in the surface roughness of the front face of the sheet base material 11a is so set that it is equal to or larger than the wavelength λ of laser light L used.

To make the front face of the sheet base material 11a a roughened surface, any processing method may be used. Examples of the processing method include: a method in which the sheet base material 11a is immersed in acid solution or alkaline solution that affects the sheet base material 11a and chemically treated; a method in which the sheet base material is processed by mechanical polishing, such as sandblast; and a method in which the sheet base material is processed by pressing, that is, a jig with projections and depressions formed in its front face is pressed against the sheet base material 11a.

### Fourth Embodiment

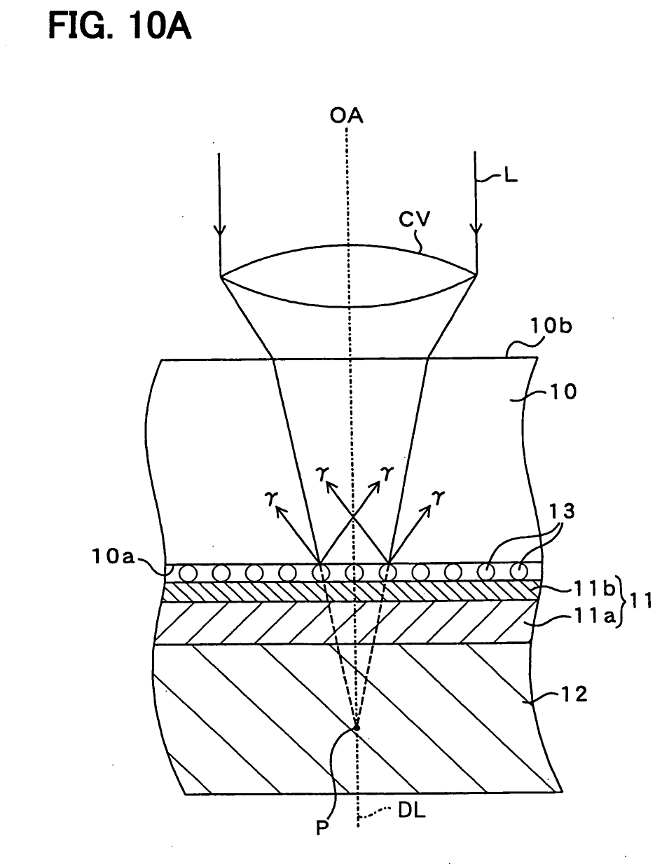

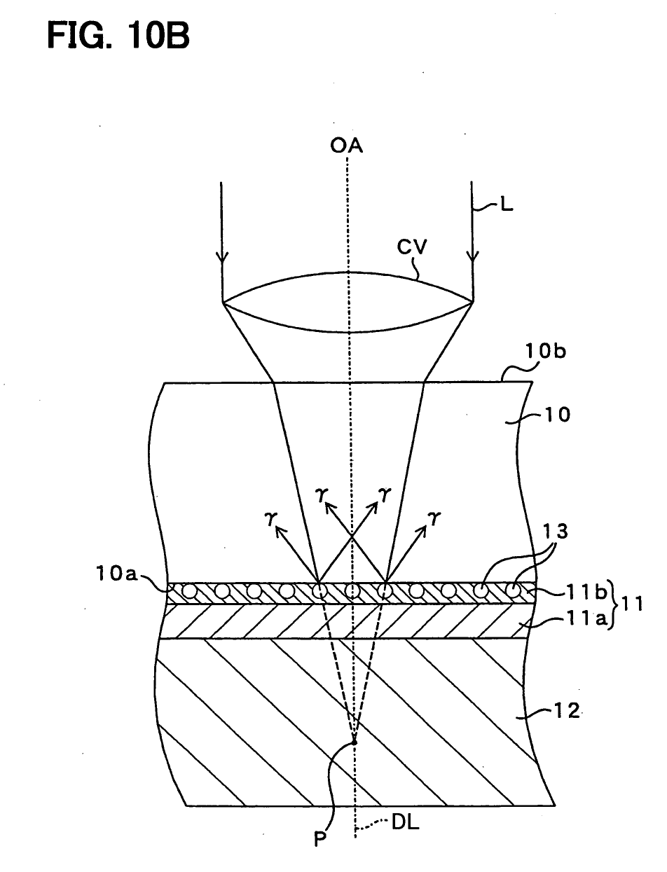

In the fourth embodiment shown in FIG. 10A, the rear face 10a of the wafer 10 is a smooth surface and the dicing sheet 11 is formed of the sheet base material 11a and the binding material 11b as described in Sections 2.1 and 2.2 with respect to the second embodiment.

The fourth embodiment is different from the second embodiment in the following points:

(4.1) The front faces of the sheet base material 11a and the binding material 11b are smooth surfaces.

(4.2) A large number of substantially spherical particles 13 are scattered and bonded to the flat front face of the binding material 11b to provide the protective layer.

(4.3) The rear face 10a of the wafer 10 is in contact with the front face of the binding material 11b only at its portions without particles 13. FIG. 10A does not show the state in which the rear face 10a of the wafer 10 is in contact with the front face of the binding material 11b. However, since the particles 13 are small in particle diameter and the binding material 11b is highly flexible, the following can be implemented by pressing the dicing sheet 11 against the rear face 10a of the wafer 10: the dicing sheet 11 can be stuck to the wafer 10 by the portions of the front face of the binding material 11b where particles 13 are not placed.

In the fourth embodiment, a large number of particles 13 are substantially evenly scattered on the front face (the face joined with the wafer 10) of the binding material 11b. This makes the front face of the binding material 11b an apparent roughened surface. Therefore, even when the light-converging point P is erroneously set to a point beyond the rear face 10a of the wafer 10, the above problem does not arise. Since laser light L is scattered by the particles 13 as indicated by arrows γ, the light-converging point P is not formed. As a result, the energy of laser light L at the erroneously set light-converging point P is significantly attenuated.

Therefore, the same effect as in the first embodiment is provided in the fourth embodiment. Also, in the fourth embodiment, the above effect can be provided without fail due to the same operation as in the first embodiment by taking the following measure: the maximum height Rmax in the apparent surface roughness of the front face of the binding material 11b where the particles 13 are scattered is so set that it is equal to or larger than the wavelength λ of laser light L used.

The maximum height Rmax in the apparent surface roughness of the front face of the binding material 11b where the particles 13 are scattered is substantially equal to the particle diameter of the particles 13.

Any material (e.g. glass, ceramics, plastic) can be used as the material for forming the particles 13. The same material as the material for forming the sheet base material 11a or the binding material 11b may be used or a material different from them may be used. With respect to the material for forming the particles 13 and the refractive index and reflectance of this material, optimum ones can be experimentally selected by cut-and-try methods so that the above-mentioned action and effect can be provided.

### Fifth Embodiment

The fifth embodiment shown in FIG. 10B is different from the fourth embodiment in the following points:

(5.1) A large number of substantially spherical particles 13 are substantially evenly buried in the binding material 11b. The refractive index and reflectance of the particles 13 are different from the refractive index and reflectance of the binding material 11b. This means that a large number of the particles 13 are substantially evenly scattered and fixed on the front face of the sheet base material 11a.

(5.2) The entire rear face 10a of the wafer 10 is bonded to the front face of the binding material 11b.

In the fifth embodiment, as described above, a large number of particles 13 are substantially evenly scattered on the front face (the face in contact with the binding material 11b) of the sheet base material 11a. This makes the front face of the sheet base material 11a an apparent roughened surface. Therefore, even when the light-converging point P is erroneously set to a point beyond the rear face 10a of the wafer 10, the above problem does not arise. Since laser light L is scattered by the particles 13, as indicated by arrows γ, the light-converging point P is not formed. As a result, the energy of laser light L at the erroneously set light-converging point P is significantly attenuated. Therefore, the same effect as in the first embodiment is provided in the fifth embodiment.

Also, in the fifth embodiment, the above effect can be provided without fail due to the same operation as in the first embodiment by the taking the following measure: the maximum height Rmax in the apparent surface roughness of the front face of the sheet base material 11a where the particles 13 are scattered is so set that it is equal to or larger than the wavelength λ of laser light L used.

The maximum height Rmax in the apparent surface roughness of the front face of the sheet base material 11a where the particles 13 are scattered is substantially equal to the particle diameter of the particles 13.

(Modifications)

The first to fifth embodiments may be modified in the following manner.

(1) The bulk silicon wafer 10 may be replaced with a wafer formed of semiconductor material for forming a wafer of multilayer structure. Example of wafers used in this case include: wafer of bonding SOI (Semiconductor On Insulator) structure; wafer of SIMOX (Separation by IMplanted OXygen) structure; wafer of SOI structure in which polycrystalline silicon or amorphous silicon is formed over an insulating substrate of glass or the like by solid phase epitaxy or melt recrystallization; wafer for use in light-emitting devices, obtained by crystal growing a III-V compound semiconductor layer over a substrate of sapphire or the like; and wafer formed by sticking together a silicon substrate and a glass substrate using anodic bonding.

(2) The bulk silicon wafer 10 may be replaced with any kind of wafer as long as the wafer is formed of semiconductor material (e.g. gallium arsenide) for forming a wafer (e.g. gallium arsenide substrate).

Further it may be replaced with a wafer formed of any of various materials (e.g. material containing glass). In this case, the reformed region R due to multiphoton absorption is not limited to those including a molten processed region as in the above embodiments. It may be appropriately formed in accordance with the material for forming the wafer. For example, in cases where the material for forming a wafer contains glass, the reformed region R due to multiphoton absorption can be so formed that it includes a crack region or a region where the refractive index is varied.

(3) The wafer 10 may be cut and separated by taking the following measure: the curved surface (convex face) of an object having a curvature (e.g. semi-spherical object) is pressed against a line along which the wafer 10 should be cut, and pressing force is applied. Shearing stress is thereby produced in the reformed region R to cut and separate the wafer 10.

(4) Aside from the dicing sheet 11, a dedicated light scattering member may be provided; the light scattering member may be bonded to the rear face 10a of the wafer 10, which is in turn irradiated with laser light L to form the reformed region R; thereafter, the light scattering member maybe removed from the wafer 10, and subsequently, the dicing sheet 11 may be bonded to the rear face 10a of the wafer 10.

### Sixth Embodiment

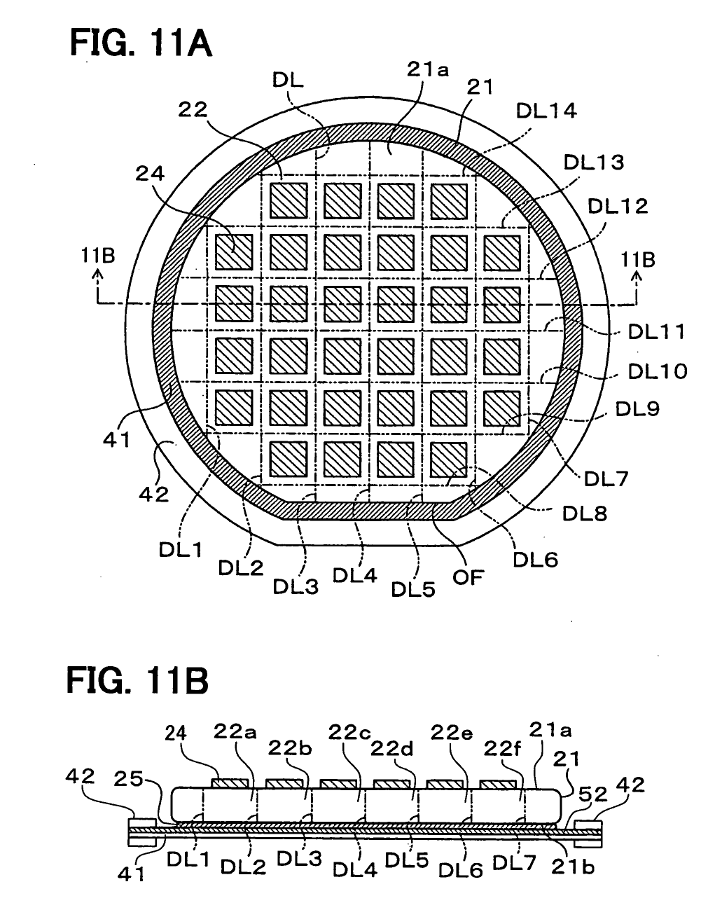

In the sixth embodiment, as shown in FIGS. 11A and 11B, a thin-plate, disk-shaped wafer 21 is formed of silicon. The wafer 21 is bonded to a resin sheet 41 at its rear face 21b opposite its laser light incident face 21a, which is a substrate surface face. The sheet has a bonding layer 52 (FIG. 11B) formed of an adhesive or the like over its entire surface, and has extensibility. The peripheral portion of the sheet 41 is held by an annular frame 42 so that the sheet 41 is tightened to provide a wafer product.

At part of the peripheral portion of the wafer 21, there is formed an orientation flat OF that indicates crystal orientation. Over the light incident face 21a of the wafer 21, semiconductor devices 24 formed through a diffusion process and the like are aligned and disposed in a grid pattern.

In the light incident faces 21a between the individual semiconductor devices 24, planned dividing lines DL1 to DL14 are established so that they extend toward the rear face 21b in the direction of the thickness of the wafer 21. The planned dividing lines are lines along which the wafer 21 is to be diced and divided in the direction of its thickness. The planned dividing lines DL1 to DL7 are provided in the direction substantially perpendicular to the orientation flat OF so that they are parallel to one another. The planned dividing lines DL8 to DL14 are provided in the direction substantially parallel to the orientation flat OF so that they are parallel to one another. That is, the planned dividing lines DL1 to DL7 and the planned dividing lines DL8 to DL14 perpendicularly intersect each other.

Each semiconductor device 24 is surrounded with planned dividing lines DL on its four sides. The wafer 21 is divided in the direction of its thickness along the planned dividing lines DL, and multiple semiconductor chips 22 having a semiconductor device 24 are thereby obtained.

An aluminum sheet 25, several micrometer in thickness, is formed over the entire rear face 21b of the wafer 21 by sputtering (FIG. 11B). The aluminum sheet 25 is easily formed and is high in adhesion to the wafer 21 and in efficiency of reflecting laser light. The aluminum sheet 25 is formed by a sputtering technique, one of dry processes; therefore, it is unlikely that semiconductor devices 24 are affected in a sheet formation process. The sheet 25 is provided as a protection layer that protects the sheet 41 from the laser light.

In the following description, portions that have not been divided from a wafer 21 and are supposed to become semiconductor chips after the substrate is divided will also be referred to as semiconductor chips. These semiconductor chips 22 are formed by dividing a wafer along the planned dividing lines DL in the direction of its thickness in a dicing process. Thereafter, they are subjected to various processes, such as mount process, bonding process, and encapsulating process, and thereby brought to completion as packaged ICs and LSIs.

As illustrated in FIG. 11B, six semiconductor chips 22a to 22f having respective semiconductor devices 24 thereon are formed over the wafer 21 along line 11B-11B. The wafer 21 has its rear face 21b bonded to the bonding layer 52 with the aluminum sheet 25 in-between. The aluminum sheet 25, bonding layer 52 and sheet 41 are disposed in this order from the rear side 21b of the wafer 21.

To part these semiconductor chips 22a to 22f from one another, seven planned dividing lines DL1 to DL7 and planned dividing lines DL11 and DL12 (FIG. 11A) that are not shown in FIG. 11B are established. Reformed regions R that become starting points for division are formed on the planned dividing lines DL1 to L7, DL11, and DL12 in the direction of the thickness of the wafer 21 by the method described later.

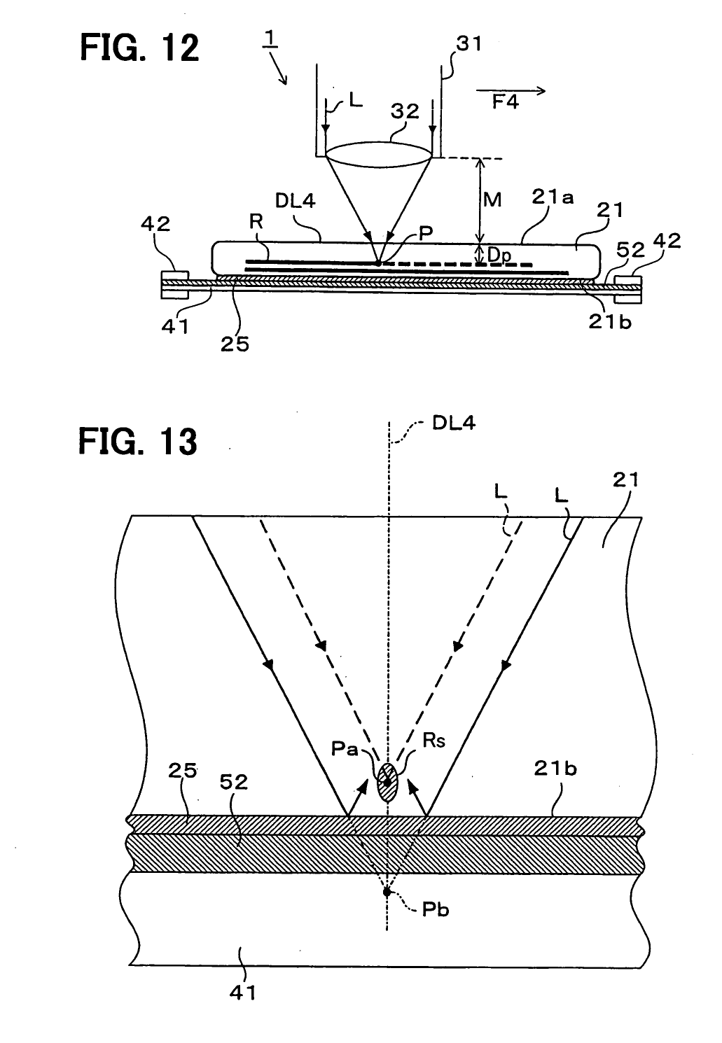

As illustrated in FIG. 12, a manufacturing machine 1 such as a laser machine for semiconductor chips is provided with a laser head 31 that projects laser light L. The laser head 31 has a condenser lens 32 that converges laser light L and is capable of converging laser light L at a predetermined focal position. In this example, the laser head is so set that the light-converging point P of laser light L is formed at a place at a depth of Dpp from the light incident face 21a within the wafer 21.

To form the reformed region R within the wafer 21, one of the planned dividing lines DL illustrated in FIG. 11A is scanned with laser light L for wafer detection, and a range to be irradiated with laser light L is set. It is assumed here that the reformed regions R are formed on the planned dividing line DL4 as an example.

The laser head 31 is caused to make scanning movement along the planned dividing line DL4 (in the direction indicated by arrow F4), as illustrated in FIG. 12. Then, laser light L is applied from the light incident face 21a side. As a result, the reformed region R due to multiphoton absorption is appropriately formed in the path at a depth of Dp through which the light-converging point P of the laser light L is caused to make scanning movement.

At this time, an arbitrary number of layers of reformed region R can be formed at an arbitrary depth within the range of the thickness of the wafer 21 by adjusting the depth Dp of the light-converging point P of the laser light L. In cases where the wafer 21 is relatively thick, for example, the light-converging point P is moved in the direction of its thickness, and the reformed region R is formed continuously or at multiple points on the planned dividing line DL in the direction of the thickness of the substrate. Thus, the wafer 21 can be divided without fail.

It is assumed that a reformed region Rs is formed on the planned dividing line DL4 within the wafer 21 in the vicinity of its rear face 2b, as illustrated in FIG. 13. Even when the light-converging point of laser light L is shifted toward the sheet 41 from an intended light-converging point Pa at which the reformed region Rs is supposed to be formed and is moved to a light-converging point Pb inside the sheet 41 and outside the wafer 21, no problem arises. Since the aluminum sheet 25 is formed over the rear face 21b of the wafer 21, laser light L is reflected by the aluminum sheet 25 before it is converged at the position Pb. Therefore, since the laser light L is not really converged at the light-converging point Pb, it is unlikely that the quality of the bonding layer 52 or the sheet 41 is changed by heat affection.

That is, even when the wafer 21 is irradiated with laser light L in the vicinity of its rear face 21b, it is unlikely that the laser light L passes through the wafer 21 to be converged within the sheet 41. Therefore, the reformed region R can be formed aiming at the vicinity of the rear face 21b that becomes a starting point for division. Also, with respect to the other planned dividing lines DL, the reformed regions R are formed in the vicinity of the rear face 21b as with the planned dividing line DL4.

Subsequently, the sheet 41 is expanded in the direction of plane to apply stress to the wafer 21. Cracks or cuts are thereby developed with the reformed regions R taken as starting points to divide the wafer 21 along the planned dividing lines DL in the direction of thickness.

An example of methods for expanding the sheet 41 is a publicly known method in which the following procedure is taken: with the frame 42 fixed, a pressing apparatus, not shown, having a flat face in substantially the same size as the rear face 21b of the wafer 21 is used; using this apparatus, the wafer 21 is pressed from the rear side of the sheet 41 so that the wafer 21 is pushed up; and the sheet 41 is thereby expanded in the direction of plane to apply stress to the wafer 21 in the in-plane direction.

When the reformed regions R are formed in the vicinity of the rear face 21b of the wafer 21, they effectively act as starting points for cracking when the sheet 41 is expanded to divide the wafer 21. Therefore, the cracks can be developed by small force, and the wafer 21 can be divided without fail.

In the sixth embodiment, any material other than the aluminum sheet 25 can be used as the sheet formed over the rear face 21b of the wafer 21 as long as the material reflects laser light L. For example, any other metal sheet, such as a titanium sheet, may be formed. The sheet formation method is not limited to sputtering, and plating or the application of coating material that reflects laser light may be adopted. In cases where a metal sheet is formed by plating, the metal sheet high in adhesion to the wafer can be formed in a short time at low cost.

The sixth embodiment provides the following advantages.

(1) The aluminum sheet 25 that reflects the laser light L is formed over the rear face 21b of the wafer 21. Therefore, the light-converging point P can be restricted from being positioned within the sheet 41 by the laser light L passing through the wafer 21.

Even when the wafer 21 is irradiated with laser light L in the vicinity of its rear face 21b, it is unlikely that the laser light L passes through the wafer 21 and the sheet 41 is irradiated with it. Therefore, a sufficient amount of reformed regions R that become starting points for division can be formed aiming at the area in the vicinity of the rear face 21b.

Thus, the sheet 41 is protected from being changed by the laser light L, applied to the planned dividing lines DL, passing through the wafer 21 and being converged within the sheet 41. At the same time, the reformed regions R sufficient for wafer cutting can be formed in the vicinity of the rear face 21b of the wafer 21.

### Seventh Embodiment

In the seventh embodiment shown in FIG. 14, the reformed region R is formed by converging laser light L reflected by the aluminum sheet 25.

As illustrated in FIG. 12, the position of the light-converging point P is determined by a distance M between the laser light L projection face of the laser head 31 and the light incident face 21a. In cases where the aluminum sheet 25 is not formed, the light-converging point P is shifted more toward the sheet 41 with decrease in this distance M. When beams of laser light L1 to L5 are applied, as illustrated in FIG. 14, the laser head is so set that the distance M is shortened in this order.

The laser light L1 is converged at the light-converging point P1 that is set to a position closest to the light incident face 21a among the light-converging points P1 to P5, and the reformed region R1 is formed just below the light incident face 21a. Similarly, the reformed region P2 is formed around the light-converging point P2 by the laser light L2, and the reformed region R3 is formed around the light-converging point P3 by the laser light L3. That is, the reformed regions R1 to R3 are formed by the beams of laser light L1 to L3, incident on the wafer 21, being directly converged at the light-converging points P1 to P3.

Without the aluminum sheet 25, the laser light L4 would be converged at a light-converging point Pm within the bonding layer 52. With the aluminum sheet 25 provided, however, it is reflected by the sheet 25 before it is converged there. It is converged at the light-converging point P4 set between the light-converging point P3 and the rear face 21b, and the reformed region R4 is formed around it. Similarly, without the aluminum sheet 25, the laser light L5 would be converged at a light-converging point Pn within the sheet 41. With the aluminum sheet 25 provided, it is reflected by the sheet before it is converged there. It is converged at the light-converging point P5 set between the light-converging point P2 and the light-converging point P3, and the reformed region R5 is formed around it.

When reformed regions R are formed in the increasing order of distance from the light incident face 21a when multiple layers of reformed region R are introduced in the direction of the thickness of the wafer 21, the laser light L passes through the reformed region R already having been formed before and it is scattered. Thus, the light-converging point P becomes less prone to be formed. As a result, the reformed region R having sufficient dimensions may not be formed. To cope with this, it is desirable to form the reformed regions R in the decreasing order of distance from the light incident face 21a.

Therefore, it is desirable that the reformed regions R should be formed in the order of R4, R3, R5, R2 to R1. The distance M (FIG. 12) between the laser head 31 and the light incident face 21a is so controlled that the beams of laser light L are projected in the order of L4, L3, L5, L2 to L1.

The seventh embodiment provides the following advantages.

(1) In the reformed region formation process, laser light L applied to the inside of wafer 21 is reflected by the aluminum sheet 25 formed over its rear face 21b. The light-converging point P of the reflected laser light L is positioned within the wafer 21, and the reformed region R is thereby formed. Therefore, the reformed region R can be efficiently formed by making good use of the energy of the reflected laser light L.

(2) The laser light L reflected by the aluminum sheet 25 is converged to form reformed regions R4 and K5 in the vicinity of the rear face 21b. Thus, a sufficient number or amount of reformed regions R to become starting points for division can be formed in the vicinity of the rear face 21b. The reformed region R formed in the vicinity of the rear face 21b becomes a starting point for the development of cracks on a planned dividing line DL when the wafer 21 is divided by expanding the sheet 41. Therefore, the wafer 21 can be divided by smaller force by forming a sufficient number or amount of reformed regions R. Consequently, the wafer 21 can be divided easily, and portions left undivided can be eliminated.

### Eighth Embodiment

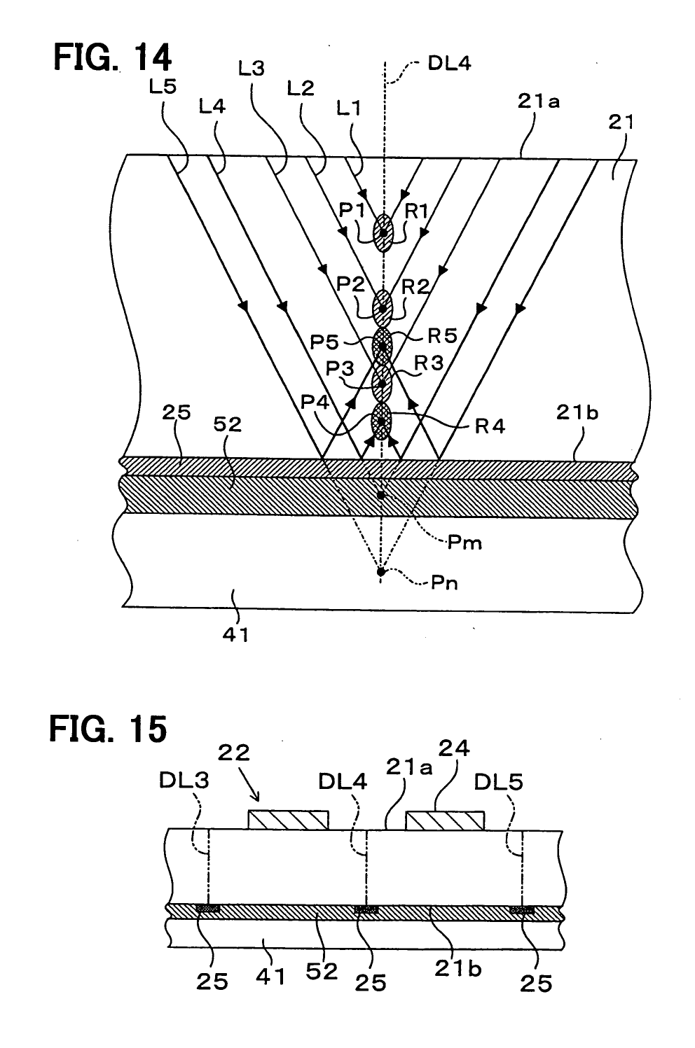

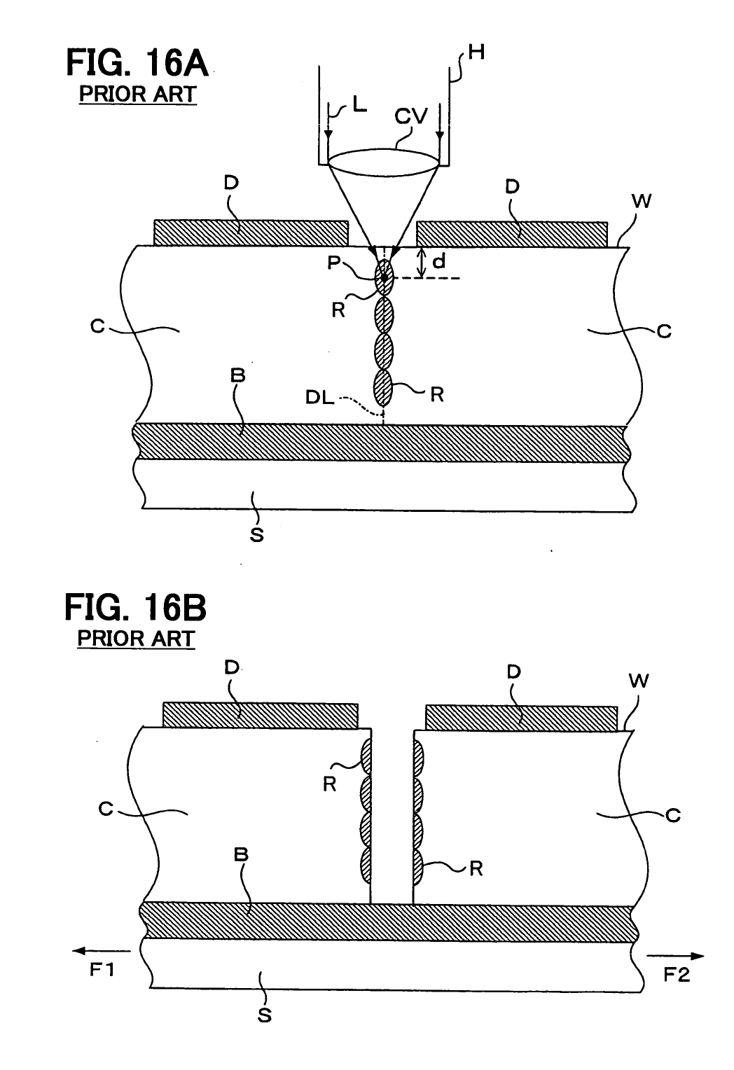

In the eighth embodiment shown in FIG. 15, the aluminum sheet 25 is formed over the rear face 21b only along the planned dividing lines DL. The aluminum sheet 25 is formed on the planned dividing lines DL3 to DL5 in shape of strip having a width of, for example, approximately 1/10 of the length of a side of each semiconductor chip 22. When the entire rear face 21b of the wafer 21 is viewed, the aluminum sheet 25 is formed on the planned dividing lines DL1 to DL14 in a grid pattern. Even in cases where this construction is adopted, the aluminum sheet 25 is capable of reflecting laser light L applied to the planned dividing lines DL; therefore, the same advantage as in the first and second embodiments can be provided. Further, most of regions in the rear face 21b other than the regions where the aluminum sheet 25 is formed are directly bonded to the bonding layer 52, and the wafer 21 can be firmly bonded to the sheet 41. In the dividing process, therefore, stress can be applied to the wafer 21 with reliability, and the substrate can be divided without fail.

Instead, metal foil, such as aluminum foil, may be placed in a lattice pattern on the bonding layer 52 in the positions corresponding to the planned dividing lines DL.

In the sixth to eighth embodiments, the wafer 21 may be an oxide sheet composed of oxide silicon formed over its light incident face 21a and a wafer of SOI (Silicon On Insulator) and the like.

What is claimed is:

1. A wafer product cut and separated by cutting with a reformed region due to multiphoton absorption, formed by laser light applied with a light-converging point positioned as a starting point for cutting, the wafer product comprising:
a wafer having two faces, one of which is a laser light incident face,
wherein an other face opposing the laser light incident face is roughened to have substantially uniform projections and depressions thereon.

2. A wafer product cut and separated by cutting with a reformed region due to multiphoton absorption, formed by laser light applied with a light-converging point positioned as a starting point for cutting, the wafer product comprising:
a wafer having two faces, one of which is a laser light incident face; and
a light scattering member bonded to an other face opposing the laser light incident face to scatter the laser light passing through the wafer.

3. The wafer product according to claim 2, wherein:
the light scattering member includes a base material and a binding material composed of an adhesive for bonding the base material to the wafer; and
the binding material has a face, which is joined with the wafer and is roughened to have substantially uniform projections and depressions.

4. The wafer product according to claim 2, wherein:
the light scattering member includes a base material and a binding material composed of an adhesive for bonding the base material to the wafer; and
the base material has a face, which is in contact with the binding material and is roughened to have substantially uniform projections and depressions.

5. The wafer product according to claim 2, wherein the light scattering member includes:
a base material;
a binding material composed of an adhesive for bonding the base material to the wafer; and
a number of particles substantially evenly scattered and bonded on a face of the binding material joined with the wafer, the particles making the face of the binding material joined with the wafer an apparent roughened surface to have substantially uniform projections and depressions.

6. The wafer product according to claim 2, wherein the light scattering member includes:
a base material;
a binding material composed of an adhesive for bonding the base material to the wafer; and
a number of particles substantially evenly buried in the binding material, the particles having a refractive index and reflectance different from a refractive index and a reflectance of the binding material, and the particles making the face of the base material in contact with the binding material an apparent roughened surface to have substantially uniform projections and depressions.

7. The wafer product according to claim 2, wherein:
the light scattering member is a dicing sheet that is stretched to thereby apply tensile stress to the reformed region and causes cutting with the reformed region taken as the starting point for cutting.

8. The wafer product according to claim 2, wherein:
a maximum height of projections and depressions of a surface roughness is equal to or larger than a wavelength of the laser light.

9. A processing method for a wafer product comprising:
forming, on a face of a wafer that is opposite to a laser light incident face of the wafer, a roughened surface to have substantially uniform projections and depressions; and
applying a laser light to the wafer in a direction from the laser light incident face to the roughened surface, so that the wafer is cut and separated by cutting with a reformed region due to multiphoton absorption formed inside the wafer by the laser light.

10. A processing method for a wafer product comprising:
bonding a light scattering member for scattering a laser light to a face of a wafer that is opposite a laser light incident face of the wafer; and
applying a laser light to the wafer in a direction from the laser light incident face toward the light scattering member, so that the wafer is cut and separated by cutting with a reformed region due to multiphoton absorption formed inside the wafer by the laser light.

11. The processing method according to claim 10, further comprising:
forming the light scattering member by a base material and a binding material composed of an adhesive for bonding the base material to the wafer; and
forming, on a face of the binding material bonded to the wafer, a roughened surface to have substantially uniform projections and depressions.

12. The processing method according to claim 10, further comprising:
forming the light scattering member by a base material and a binding material composed of an adhesive for bonding the base material to the wafer,
forming, on a face of the base material in contact with the binding material, a roughened surface to have substantially uniform projections and depressions.

13. The processing method according to claim 10, further comprising:
forming the light scattering member by a base material, a binding material composed of an adhesive for bonding the base material to the wafer, and a number of particles substantially evenly scattered and bonded on a face of the binding material to be joined with the wafer,
wherein the particles make the face of the binding material joined with the wafer an apparent roughened surface to have substantially uniform projections and depressions.

14. The processing method according to claim 10, further comprising:
forming the light scattering member by a base material, a binding material composed of an adhesive for bonding the base material to the wafer, and a number of particles substantially evenly buried in the binding material,
wherein a refractive index and a reflectance of the particles are different from a refractive index and a reflectance of the binding material, and
wherein the particles make the face of the base material in contact with the binding material an apparent roughened surface to have substantially uniform projections and depressions.

15. The processing method according to claim 10, wherein:
the light scattering member is a dicing sheet that is stretched and thereby applies tensile stress to the reformed region and causes cutting with the reformed region taken as a starting point for cutting.

16. The processing method according to claim 10, wherein:
a maximum height of projections and depressions of a surface roughness is equal to or larger than a wavelength of the laser light.

17. A processing method for a wafer product comprising:
bonding a sheet to a wafer:
forming a reflector between the sheet and the wafer on at least a planned dividing line to reflect light incident thereto;
applying laser light to the wafer toward the sheet with a light-converging point positioned inside the wafer to form a reformed region due to multiphoton absorption at the light-converging point, while moving the laser light relative to the wafer along the planned dividing line for dividing the wafer in a direction of a thickness thereof; and
expanding the sheet to divide the wafer in the direction of the thickness thereof along the planned dividing line with the reformed region taken as a starting point.

18. The processing method according to claim 17, wherein:
the reflector is formed of a metal sheet.

19. The processing method according to claim 18, wherein:
the metal sheet is formed mainly of aluminum.

20. The processing method according to claim 17, wherein:
the applying laser light includes moving the laser light in the direction of the thickness so that the laser light is converged inside the wafer after passing through the wafer and reflecting at the reflector.

21. The processing method according to claim 20, wherein:
the reformed region is formed in a vicinity of a face where the sheet is bonded to the wafer.

22. A wafer product separable by cutting at a reformed region formed by laser light, the wafer product comprising:
a wafer having two faces, one of which is a laser light incident face and an other of which is opposite the light incident face in a direction of wafer thickness;
a dicing sheet attached to the other face of the wafer for cutting the wafer into a plurality of chips when stretched; and
a protection layer provided between the wafer and the dicing sheet for scattering or reflecting the laser light passing though the wafer thereat to protect the dicing sheet from the laser light.
